(19) United States
(12) Patent Application Publication
(10) Pub. No.: US 2024/0133974 A1
(43) Pub. Date: Apr. 25, 2024

(54) BATTERY MONITORING SYSTEM, BATTERY MONITORING DEVICE, MEASUREMENT DEVICE, BATTERY MONITORING METHOD, AND NON-TRANSITORY COMPUTER-READABLE RECORDING MEDIUM

(71) Applicants: DENSO TEN Limited, Kobe-shi (JP); DENSO CORPORATION, Kariya-shi (JP)

(72) Inventors: Hiroshi OHTANI, Kobe (JP); Shogo SHIGEMORI, Kariya (JP)

(73) Assignees: DENSO TEN Limited, Kobe-shi (JP); DENSO CORPORATION, Kariya-shi (JP)

(21) Appl. No.: 18/489,958

(22) Filed: Oct. 18, 2023

(30) Foreign Application Priority Data
Oct. 20, 2022 (JP) 2022-168938
Sep. 6, 2023 (JP) 2023-145474

(51) Int. Cl. G01R 31/396; G01R 31/371; G01R 31/392

(52) U.S. Cl. CPC G01R 31/396; G01R 31/371; G01R 31/392

(57) ABSTRACT

A battery monitoring system includes measurement devices and a battery monitoring device. Each measurement device measures a cell state of a corresponding cell constituting a battery. The battery monitoring device sequentially communicates, by using wireless communication, with the measurement devices during a communication period; and acquires state information indicating the cell state from each measurement device. In a case where transmitting a measurement instruction of the cell state to each of the measurement devices, the battery monitoring device transmits, to each of the plurality of measurement devices, a corresponding stand-by time interval such that measurement timings of the measurement devices synchronize, the stand-by time interval being a time interval from reception of the measurement instruction until the measurement timing. Each of the measurement devices measures the corresponding cell state in a case where the stand-by time interval has elapsed since reception of the measurement instruction.

### CROSS-REFERENCE TO RELATED APPLICATION

This application is based upon and claims the benefit of priority of the prior Japanese Patent Application No. 2022-168938, filed on Oct. 21, 2022 and Japanese Patent Application No. 2023-145474, filed on Sep. 7, 2023, the entire contents of which are incorporated herein by reference.

### FIELD

The embodiment discussed herein is directed to a battery monitoring system, a battery monitoring device, a measurement device, a battery monitoring method, and a non-transitory computer-readable recording medium.

### BACKGROUND

Recently, in a field of a battery monitoring system, there has been proposed a technology for connecting, by using wireless communication, a plurality of slave machines each of which measures states of a plurality of cells constituting a battery, and a master machine that acquires states of the cells from the respective slave machines so as to monitor the battery.

Moreover, in such a kind of a battery monitoring system, slave machines are generally not communicably connected with each other, and thus it is necessary for a master machine to synchronize measurement timings of slave machines in order to match measurement timings of the slave machines.

Regarding the above-mentioned point, in Japanese Laid-open Patent Publication No. 2022-535122, a master machine simultaneously transmits a sampling signal to slave machines by a broad casting method so as to synchronize sampling (measurement) between the slave machines.

However, a conventional technology is in the premise of simultaneous transmission by a broad casting method, and thus, for example, if a unicast method is employed for executing one-on-one sequential communication with slave machines by using wireless communication during a communication period, there presents possibility that measurement timings are not synchronized.

Specifically, in Japanese Laid-open Patent Publication No. 2022-535122, a sampling signal is simultaneously transmitted to all of slave machines at once by using a broad casting method, and all of the slave machines execute measurement in accordance with the simultaneously-received sampling signals, so as to synchronize measurement timings.

Herein, if sampling signals are transmitted by using a unicast method, timings for receiving the sampling signals are different between slave machines, and thus it may be impossible to synchronize measurement timings between the slave machines even if measurement is executed in accordance with the sampling signals.

### SUMMARY

In order to solve the above-mentioned problem and further to achieve an object, a battery monitoring system according to an embodiment includes a plurality of measurement devices and a battery monitoring device. Each of the plurality of measurement devices measures a cell state of a corresponding one of a plurality of cells constituting a battery. The battery monitoring device sequentially communicates, by using wireless communication, with the plurality of measurement devices during a communication period; and acquires state information indicating the cell state from each of the plurality of measurement devices. In a case where transmitting a corresponding measurement instruction of the cell state to each of the plurality of measurement devices, the battery monitoring device transmits, to each of the plurality of measurement devices, a corresponding stand-by time interval such that measurement timings of the plurality of measurement devices synchronize with each other, the stand-by time interval being a time interval from reception of the measurement instruction until the measurement timing. Each of the plurality of measurement devices measures the corresponding cell state in a case where the stand-by time interval has elapsed since reception of the measurement instruction.

### BRIEF DESCRIPTION OF DRAWING(S)

FIG. 1A is a block diagram illustrating a configuration example of a battery monitoring system according to an embodiment;

FIG. 1B is a diagram illustrating an operation example of the battery monitoring system according to the embodiment;

FIG. 2 is a block diagram illustrating a functional configuration example of a battery monitoring device according to the embodiment;

FIG. 3 is a block diagram illustrating a functional configuration example of a measurement device according to the embodiment;

FIG. 4 is a diagram illustrating a synchronization process of acquisition timings of current values;

FIG. 5 is a diagram illustrating a calculation method of a stand-by time interval;

FIG. 6 is a timing diagram illustrating a processing procedure of processes that are executed in the battery monitoring system according to the embodiment;

FIG. 7 is a diagram illustrating a process for detecting presence/absence of failure in a measuring process in the measurement device;

FIG. 8 is a diagram illustrating a process for detecting presence/absence of failure in reception of a measurement instruction in the measurement device;

FIG. 9 is a diagram illustrating a process for detecting presence/absence of failure in a measuring process in the measurement device;

FIG. 10 is a diagram illustrating a configuration example of a battery monitoring system according to a modification;

FIG. 11 is a diagram illustrating a configuration example of a battery monitoring system according to the modification;

FIG. 12 is a flowchart illustrating a processing procedure of processes to be executed by TCU according to the modification; and

FIG. 13 is a flowchart illustrating a processing procedure of processes to be executed by the battery monitoring device according to the modification.

FIG. 14 is a diagram illustrating a hardware configuration of one example of a computer that realizes functions of the battery monitoring device.

### DESCRIPTION OF EMBODIMENTS

Hereinafter, an embodiment of a battery monitoring system, a battery monitoring device, a measurement device, a battery monitoring method, and a non-transitory computer-readable recording medium will be described in detail with reference to the accompanying drawings. Moreover, the disclosed technology is not limited to the embodiment described below.

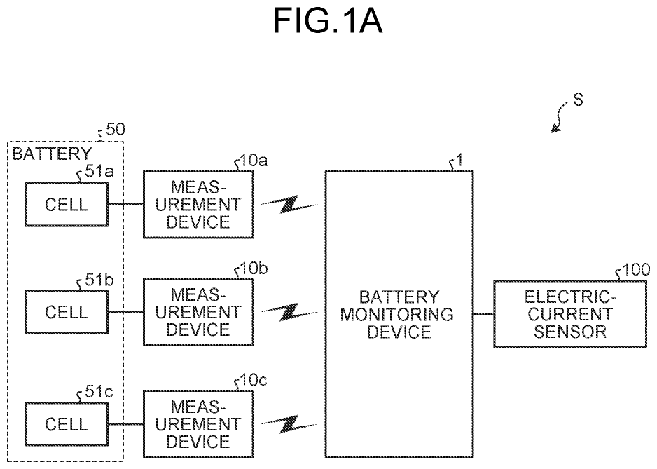

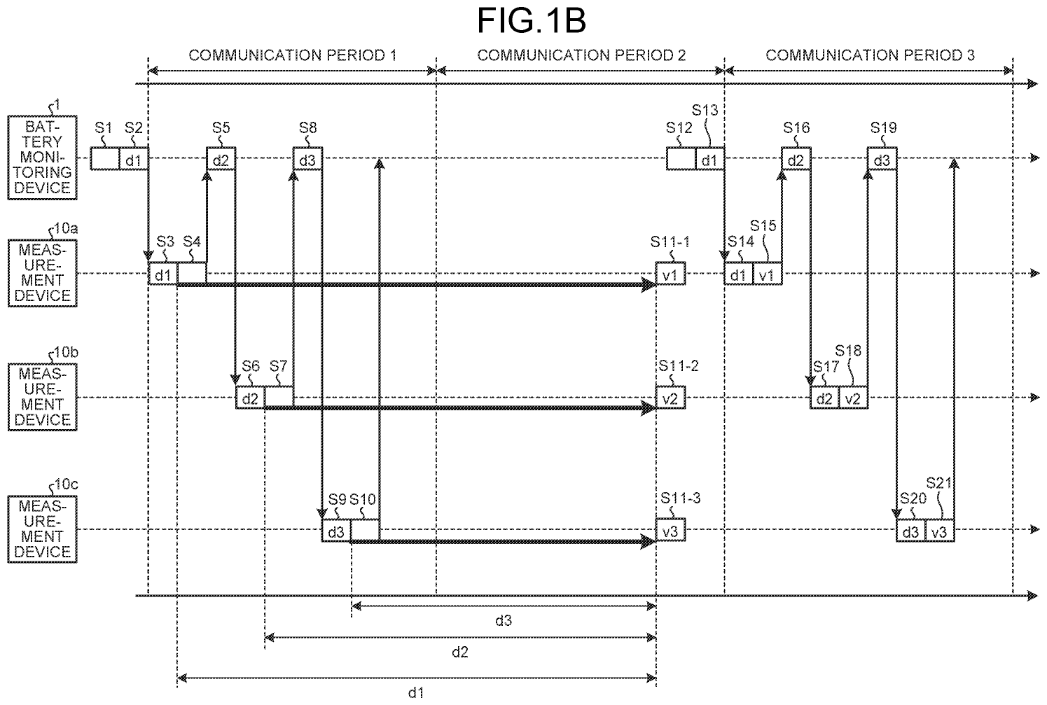

The outline of an electronic monitoring system according to the embodiment will be explained with reference to FIG. 1A and FIG. 1B. FIG. 1A is a block diagram illustrating a configuration example of a battery monitoring system S according to the embodiment. FIG. 1B is a diagram illustrating an operation example of the battery monitoring system S according to the embodiment.

The battery monitoring system S according to the embodiment is a system configured to monitor a state of a battery (for example, lithium-ion battery) for driving a vehicle, which is mounted on an electric automobile or a hybrid vehicle, for example. Note that the battery monitoring system S may be configured to monitor a state of an arbitrary battery other than a battery for vehicles.

As illustrated in FIG. 1A, the battery monitoring system S includes a battery monitoring device 1, a plurality of measurement devices 10a, 10b, and 10c, a battery 50, and an electric-current sensor 100. The battery monitoring system S illustrated in FIG. 1A calculates a cell resistance of the battery 50 from voltage information on a voltage that is output from the battery 50 in which a plurality of cells 51a, 51b, and 51c is serially connected and current information on a current flowing through the battery 50; and further monitors a deteriorated state of the battery 50 on the basis of the resistance value of the cell resistance. Hereinafter, in a case where the plurality of measurement devices 10a, 10b, and 10c is not particularly identified, the plurality of measurement devices 10a, 10b, and 10c may be comprehensively referred to as a plurality of measurement devices 10. In a case where the plurality of cells 51a, 51b, and 51c is not particularly identified, the plurality of cells 51a, 51b, and 51c may be comprehensively referred to as a plurality of cells 51.

The plurality of measurement devices 10 is respectively connected to the plurality of cells 51 constituting the battery 50 so as to measure a cell state of each of the plurality of cells 51 in accordance with a corresponding measurement instruction of the battery monitoring device 1. For example, the cell state includes a voltage (hereinafter, cell voltage) of a cell, a temperature (hereinafter, cell temperature) of a cell, and the like. Hereinafter, a case is exemplified in which the measurement device 10 measures a cell voltage as a cell state.

Specifically, the measurement device 10a measures a cell voltage of the cell 51a, the measurement device 10b measures a cell voltage of the cell 51b, and the measurement device 10c measures a cell voltage of the cell 51c.

For example, the battery monitoring device 1 is connected, by using wireless communication of time division, to each of the plurality of measurement devices 10 to be able to communicate with each other, and further acquires state information indicating a cell state from the corresponding measurement device 10. Specifically, the battery monitoring device 1 sequentially communicates, by wireless communication, with the plurality of measurement devices 10 during a communication period. In other words, the battery monitoring device 1 executes time division on a communication period, and further is communicably connected with the plurality of measurement devices 10 during a predetermined time interval by a unicast method for sequentially communicating one-on-one with the devices. Note that the communication period is a time interval until the battery monitoring device 1 completes communication with all of the measurement devices 10.

The electric-current sensor 100 measures a current flowing through the battery 50. The electric-current sensor 100 may be included in the battery monitoring device 1, or may be arranged outside of the battery monitoring device 1 and further transmits a measured current value to the battery monitoring device 1. Hereinafter, a case is exemplified in which the electric-current sensor 100 is arranged outside of the battery monitoring device 1 and further transmits a measured current value to the battery monitoring device 1 by wired connection.

In such a configuration, in the battery monitoring system S according to the embodiment, in a case where transmitting a measurement instruction of a cell state to each of the plurality of measurement devices 10, the battery monitoring device 1 transmits, to the plurality of measurement devices 10, stand-by time intervals of the plurality of measurement devices 10 from reception of the measurement instruction until a measurement timing such that measurement timings of the plurality of measurement devices 10 synchronize with each other. Each of the plurality of measurement devices 10 receives a corresponding measurement instruction by a unicast method from the battery monitoring device 1, and further measures a cell state at a measurement timing that is a timing at which a stand-by time interval has elapsed since reception of the measurement instruction.

Herein, with reference to FIG. 1B, a synchronization process of a measurement timing in the battery monitoring system S according to the embodiment will be explained. Note that in FIG. 1B, there is illustrated a processing example of the battery monitoring system S, which is executed during three continuous periods of a communication period 1 to a communication period 3.

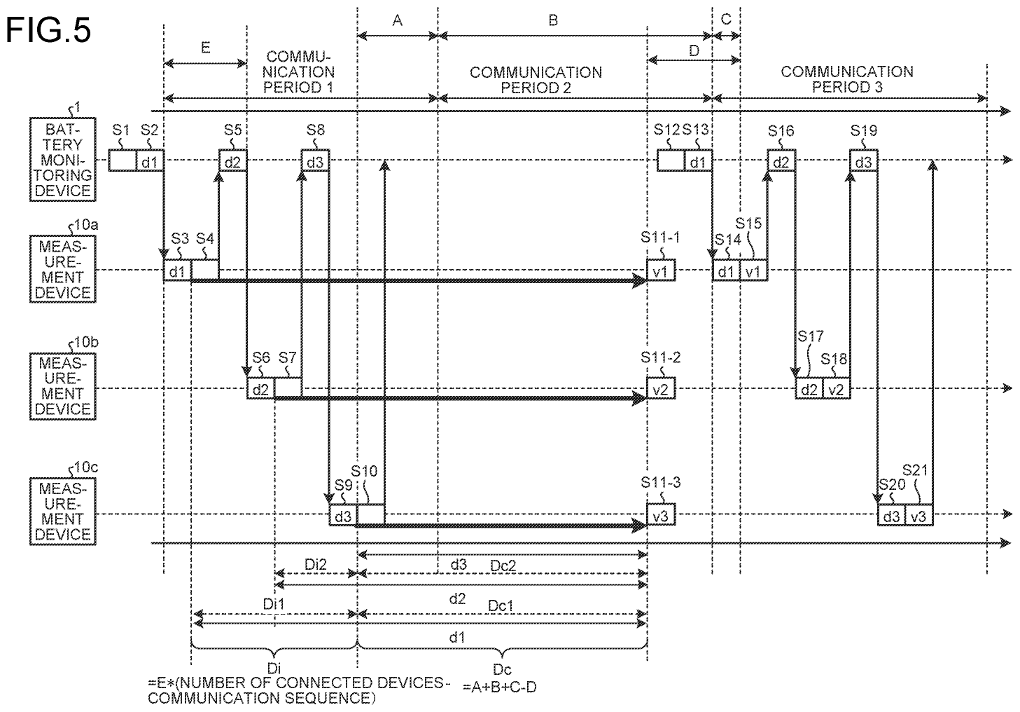

As illustrated in FIG. 1B, the battery monitoring device 1 calculates a corresponding stand-by time interval of each of the plurality of measurement devices 10a, 10b, and 10c before start of the communication period 1, in other words, before executing communication with the measurement device 10a which is a first communication sequence during the communication period 1 (S1). Note that a specific calculation method of a stand-by time interval will be mentioned later with reference to FIG. 5.

Next, the battery monitoring device 1 generates transmission data of a measurement instruction to be transmitted to the measurement device 10a, which has a first communication sequence during the communication period 1, and further transmits the generated transmission data to the measurement device 10a (S2). Specifically, the battery monitoring device 1 generates transmission data including a measurement instruction and a stand-by time interval d1 corresponding to the measurement device 10a, and further transmits the transmission data to the measurement device 10a by a unicast method.

Next, the measurement device 10a analyzes the received transmission data, and further reads information on a measurement instruction and the stand-by time interval d1 from the transmission data (S3). Next, the measurement device 10a starts to count (count up or count down) the stand-by time interval d1, and further transmits a response to the transmission data to the battery monitoring device 1 (S4). Note that in transmitting the response, the measurement device 10a may transmit, as state information, a previously measured cell voltage to the battery monitoring device 1.

Next, the battery monitoring device 1 generates transmission data of a measurement instruction, which is transmitted to the measurement device 10b having a next communication sequence, and further transmits the generated transmission data to the measurement device 10b (S5). Specifically, the battery monitoring device 1 generates transmission data that includes a measurement instruction and a stand-by time interval d2 corresponding to the measurement device 10b, and further transmits the transmission data to the measurement device 10b by a unicast method.

Next, the measurement device 10b analyzes the received transmission data, and further reads information on a measurement instruction and the stand-by time interval d2 from the transmission data. Next, the measurement device 10b starts to count the stand-by time interval d2, and further transmits a response to transmission data to the battery monitoring device 1 (S7).

Next, the battery monitoring device 1 generates transmission data of a measurement instruction, which is transmitted to the measurement device 10c having a next communication sequence, and further transmits the generated transmission data to the measurement device 10c (S8). Specifically, the battery monitoring device 1 generates transmission data that includes a measurement instruction and a stand-by time interval d3 corresponding to the measurement device 10c, and further transmits the transmission data to the measurement device 10c by a unicast method.

Next, the measurement device 10c analyzes the received transmission data, and further reads information on a measurement instruction and the stand-by time interval d3 from the transmission data (S9). Next, the measurement device 10c starts to count the stand-by time interval d3, and further transmits a response to transmission data to the battery monitoring device 1 (S10).

Herein, a time interval of each of the stand-by time intervals d1 to d3 is set to be longer as a corresponding communication sequence is later in order to synchronize measurement timings with each other. In other words, the battery monitoring device 1 calculates a time interval of each of the stand-by time intervals d1 to d3, which is from reception of a measurement instruction until a measurement timing, and further transmits the calculated time interval to corresponding one of the plurality of measurement devices 10a, 10b, and 10c such that measurement timings of the plurality of measurement devices 10a, 10b, and 10c synchronize with each other.

As illustrated in FIG. 1B, each of the plurality of measurement devices 10a, 10b, and 10c measures a corresponding cell voltage v1, v2, or v3 in a case where a corresponding one of the stand-by time intervals d1 to d3 has elapsed since reception of a measurement instruction (S11-1 to S11-3). Thus, it is possible to synchronize measurement timings of the plurality of measurement devices 10a, 10b, and 10c with each other.

Next, the battery monitoring device 1 calculates stand-by time intervals of the plurality of measurement devices 10a, 10b, and 10c before start of the communication period 3, in other words, communicating with the measurement device 10a having a first communication sequence during the communication period 3 (S12).

Next, the battery monitoring device 1 generates transmission data of a measurement instruction to be transmitted to the measurement device 10a having a first communication sequence during the communication period 3, and further transmits the generated transmission data to the measurement device 10a (S13). Specifically, the battery monitoring device 1 generates transmission data that includes a measurement instruction and the stand-by time interval d1 corresponding to the measurement device 10a, and further transmits the generated transmission data to the measurement device 10a by a unicast method.

In a case where not transmitting a measurement instruction during the communication period 3, in other words, in a case where a next measurement instruction is scheduled to be executed during a communication period that is later than the communication period 3, the battery monitoring device 1 omits a process of Step S12 so as to transmit transmission data (header alone) without information on a measurement instruction and/or a stand-by time interval to the measurement device 10a.

Next, the measurement device 10a analyzes the received transmission data, and further reads information on a measurement instruction and the stand-by time interval d1 from the transmission data (S14). Next, the measurement device 10a starts to count (count up or count down) the stand-by time interval d1, and further transmits a response to transmission data to the battery monitoring device 1 (S15). Specifically, in transmitting a response to the battery monitoring device 1, the measurement device 10a transmits, as state information, a cell voltage that is measured by the measurement device 10a itself during the communication period 2.

Next, the battery monitoring device 1 generates transmission data of a measurement instruction, which is transmitted to the measurement device 10b having a next communication sequence, and further transmits the generated transmission data to the measurement device 10b (S16). Specifically, the battery monitoring device 1 generates transmission data that includes a measurement instruction and the stand-by time interval d2 corresponding to the measurement device 10b, and further transmits the transmission data to the measurement device 10b by a unicast method.

Next, the measurement device 10b analyzes the received transmission data, and further reads information on a measurement instruction and the stand-by time interval d2 from the transmission data (S17). Next, the measurement device 10b starts to count the stand-by time interval d2, and further transmits a response to transmission data to the battery monitoring device 1 (S18). Specifically, in transmitting a response to the battery monitoring device 1, the measurement device 10b transmits, as state information, a cell voltage that is measured by the measurement device 10b itself during the communication period 2.

Next, the battery monitoring device 1 generates transmission data of a measurement instruction, which is transmitted to the measurement device 10c having a next communication sequence, and further transmits the generated transmission data to the measurement device 10c (S19). Specifically, the battery monitoring device 1 generates transmission data that includes a measurement instruction and the stand-by time interval d3 corresponding to the measurement device 10c, and further transmits the transmission data to the measurement device 10c by a unicast method.

Next, the measurement device 10c analyzes the received transmission data, and further reads information on a measurement instruction and the stand-by time interval d3 from the transmission data (S20). Next, the measurement device 10c starts to count the stand-by time interval d3, and further transmits a response to transmission data to the battery monitoring device 1 (S21). Specifically, in transmitting a response to the battery monitoring device 1, the measurement device 10c transmits, as state information, a cell voltage that is measured by the measurement device 10c itself during the communication period 2.

According to the above-mentioned processes of Step S14 to Step S21, the battery monitoring device 1 is able to acquire, during the communication period 3, all of the cell voltages that are respectively measured by the plurality of measurement devices 10a to 10c during the communication period 2.

As described above, in a case where transmitting a corresponding measurement instruction of a cell state to each of the plurality of measurement devices 10, the battery monitoring device 1 according to the embodiment calculates a corresponding stand-by time interval such that measurement timings of the plurality of measurement devices 10 synchronize with each other, the stand-by time interval being a time interval from reception of the measurement instruction until the measurement timing, and further respectively transmits the calculated stand-by time intervals to the plurality of measurement devices 10. Each of the plurality of measurement devices 10 measures a corresponding cell state in a case where the stand-by time interval has elapsed since reception of the measurement instruction, so that it is possible to synchronize measurement timings with each other.

The above-mentioned processing example of the battery monitoring system S is merely one example, and may be executed in other procedures. For example, the processes of Step S11-1 to Step S11-3 may be executed during other than the communication period 2, and may be executed after the communication period 3 in accordance with the stand-by time intervals d1 to d3 that are respectively received by the plurality of measurement devices 10a to 10c, for example.

Similarly, the processes of Step S14 to Step S21 may be executed during other than the communication period 3, and may be executed after a communication period 4, for example. In this case, cell voltages that are respectively measured by the plurality of measurement devices 10a to 10c are respectively held by the plurality of measurement devices 10a to 10c until being transmitted to the battery monitoring device 1. In a case where the processes of Step S14 to Step S21 can be executed during the communication period 2 due to a reason that the processes of Step S11-1 to Step S11-3 are completed at an early timing during the communication period 2, for example, the processes of Step S14 to Step S21 may be executed during the communication period 2.

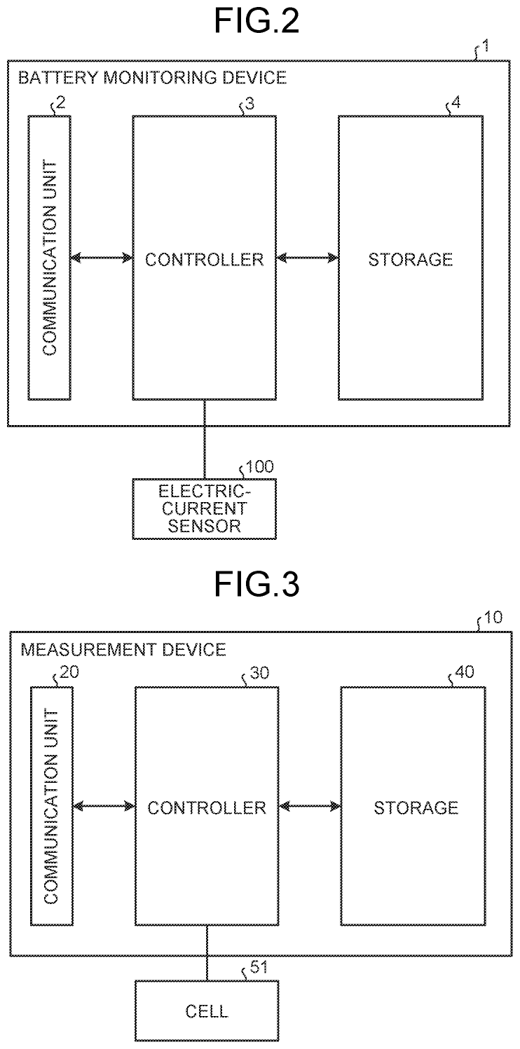

Next, functional configuration examples of the battery monitoring device 1 and the measurement device 10 will be explained with reference to FIG. 2 and FIG. 3. FIG. 2 is a block diagram illustrating a functional configuration example of the battery monitoring device 1 according to the embodiment. FIG. 3 is a block diagram illustrating a functional configuration example of the measurement device 10 according to the embodiment.

As illustrated in FIG. 2, the battery monitoring device 1 according to the embodiment includes a communication unit 2, a controller 3, and a storage 4. The controller 3 is connected to the electric-current sensor 100 in a wired manner.

For example, the communication unit 2 is a communication Integrated Circuit (communication IC) having a Bluetooth-Low-Energy communication function (BLE communication function; “Bluetooth” is Registered Trademark). The communication unit 2 executes one-on-one sequential communication with each of the plurality of measurement devices 10 during a communication period by time-divisional wireless communication. In other words, the communication unit 2 executes wireless communication by a unicast method. Furthermore, the communication unit 2 executes wired communication with the controller 3 by Serial-Peripheral-Interface communication (SPI communication), for example. The communication unit 2 executes the above-mentioned process for calculating a stand-by time interval.

The storage 4 is, for example, a Random Access Memory (RAN) or a data flash. The storage 4 is capable of storing therein state information acquired from the measurement device 10, a current value acquired from the electric-current sensor 100, information on various programs (e.g., non-transitory computer readable medium including stored instructions executed by a microprocessor) and the like. The battery monitoring device 1 may acquire the above-mentioned program and/or various kinds of information via another computer connected thereto via a wired or wireless network, or a portable recording medium.

The controller 3 includes a microcomputer including a Central Processing Unit (CPU), a Read Only Memory (ROM), a RAM, etc.; and various circuits. A CPU implements a program stored in a ROM while using a RAM as a work region, and thus the controller 3 controls overall operations of the battery monitoring device 1. A part or whole of the controller 3 may be constituted of hardware such as an Application Specific Integrated Circuit (ASIC) and a Field Programmable Gate Array (FPGA).

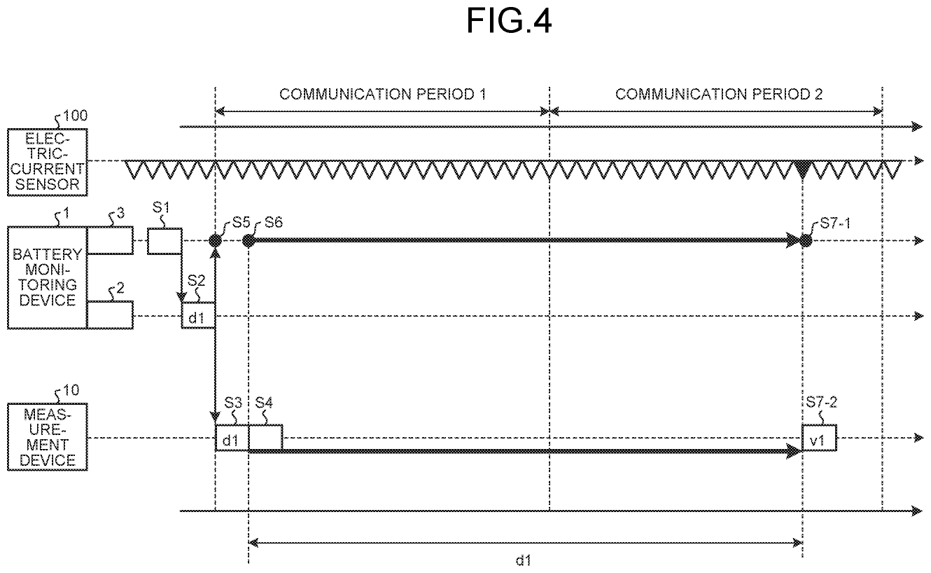

The controller 3 executes the above-mentioned transmitting process of a measurement instruction and the like. The controller 3 may executes a process for computing a stand-by time interval on behalf of the communication unit 2. On the basis of the calculated stand-by time interval, the controller 3 synchronizes a timing of acquiring a current value from the electric-current sensor 100 with a measurement timing of the measurement device 10, details thereof will be mentioned later with reference to FIG. 4.

Next, as illustrated in FIG. 3, the measurement device 10 according to the embodiment includes a communication unit 20, a controller 30, and a storage 40. The controller 30 is connected to the cell 51 in a wired manner.

The communication unit 20 is a communication IC having a BLE communication function. The communication unit 20 executes one-on-one communication with the battery monitoring device 1 at a predetermined time point during a communication period by wireless communication. In other words, the communication unit 20 executes wireless communication by a unicast method. Furthermore, the communication unit 20 executes wired communication with the controller 30 by SPI communication, for example.

The storage 40 is, for example, a Random Access Memory (RAN) or a data flash. The storage 40 is capable of storing therein a cell state measured by the measurement device 10, information on various programs (e.g., non-transitory computer readable medium including stored instructions executed by a microprocessor), and the like. The measurement device 10 may acquire the above-mentioned program and/or various kinds of information via another computer connected thereto via a wired or wireless network, or a portable recording medium.

The controller 30 includes a microcomputer including a Central Processing Unit (CPU), a Read Only Memory (ROM), a RAM, etc.; and various circuits. A CPU implements a program stored in a ROM while using a RAM as a work region, and thus the controller 30 controls overall operations of the measurement device 10. A part or whole of the controller 30 may be constituted of hardware such as an Application Specific Integrated Circuit (ASIC) and a Field Programmable Gate Array (FPGA).

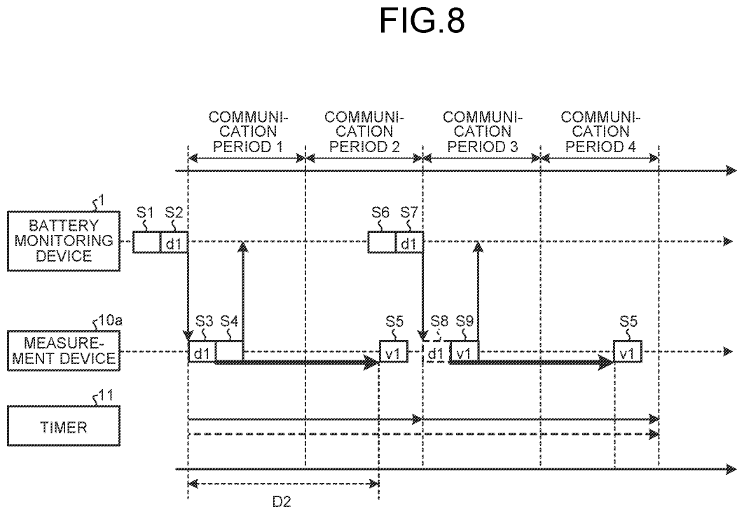

The controller 30 executes a process for measuring a cell state of the cell 51, a process for transmitting state information indicating a cell state, and the like. On the basis of time interval information measured by a timer 11, the controller 30 is capable of determining presence/absence of failure in reception of a measurement instruction, and details of this point will be explained with reference to FIG. 8.

Next, with reference to FIG. 4, a synchronization process of acquisition timings of current values, which is executed by the battery monitoring device 1, will be explained. FIG. 4 is a diagram illustrating a synchronization process of acquisition timings of current values. The battery monitoring device 1 determines measurement timings that are synchronized by stand-by time intervals as timings for acquiring current values from the electric-current sensors 100.

Specifically, the controller 3 of the battery monitoring device 1 generates transmission data of a measurement instruction to be transmitted to the measurement device 10, and further transmits the generated transmission data to the communication unit 2 by SPI communication (S1).

Next, on the basis of transmission data of a measurement instruction, the communication unit 2 of the battery monitoring device 1 calculates the stand-by time interval d1 of the measurement device 10, and further transmits transmission data including a measurement instruction and the stand-by time interval d1 to the measurement device 10 (S2).

Next, the measurement device 10 analyzes the received transmission data, and further reads information on a measurement instruction and the stand-by time interval d1 from the transmission data (S3). Next, the measurement device 10 starts to count (count up or count down) the stand-by time interval d1, and further transmits a response to the transmission data to the battery monitoring device 1 (S4).

The controller 3 of the battery monitoring device 1 monitors a communication terminal of the communication unit 2 so as to detect a transmission timing of transmission data from the communication unit 2 to the measurement device 10 (S5). Next, the battery monitoring device 1 starts to count the stand-by time interval d1 from a timing that is after a predetermined time interval from the detected transmission timing (S6). For example, the predetermined time interval is a time interval from reception of a measurement instruction by the measurement device 10 until start of counting the stand-by time interval d1, and is preliminarily set by an experiment or the like, for example.

Next, at a measurement timing after the stand-by time interval d1 elapsed, the battery monitoring device 1 acquires a current value from the electric-current sensor 100 (S7-1). The measurement device 10 measures a cell voltage at a measurement timing after the stand-by time interval d1 elapsed (S7-2).

As described above, the battery monitoring device 1 determines, as a timing for acquiring a current value from the electric-current sensor 100, measurement timings that are synchronized by a stand-by time interval, so that it is possible to synchronize a measurement timing of a cell state with an acquisition timing of a current value. In other words, in wireless communication of time division, it is possible to acquire a current value and a voltage value at a synchronized timing by using a time stamp.

Next, with reference to FIG. 5, a calculation method of a stand-by time interval will be explained. FIG. 5 is a diagram illustrating a calculation method of a stand-by time interval. Steps S1 to S21 illustrated in FIG. 5 have been already explained with reference to FIG. 1B, and thus explanation of processing details in the Steps is omitted.

As illustrated in FIG. 5, each of the stand-by time intervals d1 to d3 is a time interval obtained by totaling an individual time interval Di and a common time interval Dc. Specifically, the stand-by time interval d1 is a time interval obtained by totaling an individual time interval Di1 and a common time interval Dc1. The stand-by time interval d2 is a time interval obtained by totaling an individual time interval Di2 and a common time interval Dc2. The stand-by time interval d3 is the common time interval Dc2 (namely, individual time interval Di is zero).

More specifically, the individual time interval Di is a time interval corresponding to each of the measurement devices 10a to 10c, and the common time interval Dc is a time interval that is the same among the measurement devices 10a to 10c.

As illustrated in FIG. 5, the individual time interval Di is calculated for each of the measurement devices 10. Specifically, the individual time interval Di is a product of a time interval E multiplied by a value obtained by subtracting a communication sequence during a communication period from the connected number (three in example illustrated in FIG. 5) of the measurement devices 10 that are communicably connected during the communication period.

The time interval E is a time interval of intervals in each of which communication of the corresponding measurement device 10 is executed during a communication period. In other words, the time interval E is a guard interval.

For example, the individual time interval Di1 of the measurement device 10a has a first communication sequence during a communication period, and thus a product is the time interval E multiplied by a value obtained by subtracting a communication sequence of “1” from the number of connected devices of “3”. Thus, it is possible to precisely calculate the individual time interval Di of each of the measurement devices 10.

Next, the common time interval Dc is a time interval obtained by subtracting a time interval D from a time interval obtained by totaling a time interval A, a time interval B, and a time interval C.

The time interval A is a time interval from completion (completion of analysis of stand-by time interval d3) of receiving a measurement instruction, which is transmitted from the battery monitoring device 1, by the measurement device 10c having a final communication sequence until end of a communication period during the communication period. In other words, in FIG. 5, the time interval A is a time interval from completion of Step S9 until end of the communication period 1.

The time interval B is a time interval from end of the communication period 1 during which a measurement instruction is presently transmitted until start of the communication period 3 during which a cell state is transmitted. In other words, in FIG. 5, the time interval B is a time interval from end of the communication period 1 until start of the communication period 3.

The time interval C is a time interval from start of the communication period 3 during which a cell state is transmitted until start of transmission of a cell state from the measurement device 10a having a first communication sequence to the battery monitoring device 1. In other words, in FIG. 5, the time interval C is a time interval from start of the communication period 3 until start of Step S15 (namely, completion of Step S14).

The time interval D is a processing time interval needed for internal processing executed by the measurement device 10 during a time interval from measurement of a cell state by the measurement device 10 until transmission of a cell state to the battery monitoring device 1. In other words, in FIG. 5, the time interval D is a time interval from start of Steps S11-1 to S11-3 until start of Step S15 (namely, completion of Step S14). For example, the internal processing includes processing such as data compression of a cell state and conversion of a data format. In other words, the measurement device 10a is capable of transmitting state information upon completion of internal processing, and thus in a case where Step S15 starts under a state where internal processing is not completed, a cell state measured in Step S11-1 is transmitted during a communication period after the communication period 3. Note that in order to prevent a case where transmission of state information is not in time in a case where internal processing of the measurement device 10 takes a longer time than expected, the time interval D may be set to be longer than a processing time interval needed for the internal processing executed by the measurement device 10.

As described above, the battery monitoring device 1 acquires, during a second communication period (communication period 3), pieces of state information measured by the plurality of measurement devices 10 during a first communication period (communication period 2), the second communication period being a period just after the first communication period. In this case, the battery monitoring device 1 decides, as the measurement timing, a timing going back to past by a processing time interval (time interval D) needed for transmitting state information from a communication timing with a first one of the measurement devices 10 during the second communication period.

Thus, it is possible to transmit all cell states measured by the plurality of measurement devices 10 to the battery monitoring device 1 during the next communication period. In other words, by going back to past by a processing time interval needed for internal processing of the measurement device 10, it is possible to prevent a case where the measurement device 10 having a first communication sequence is late for transmission of a cell state due to internal processing thereof. Note that the stand-by time interval may be obtained by other than calculation, and the battery monitoring device 1 may hold a predetermined stand-by time interval. In this case, the battery monitoring device 1 does not need to execute a process for calculating a stand-by time interval, so that it is possible to reduce a load thereof.

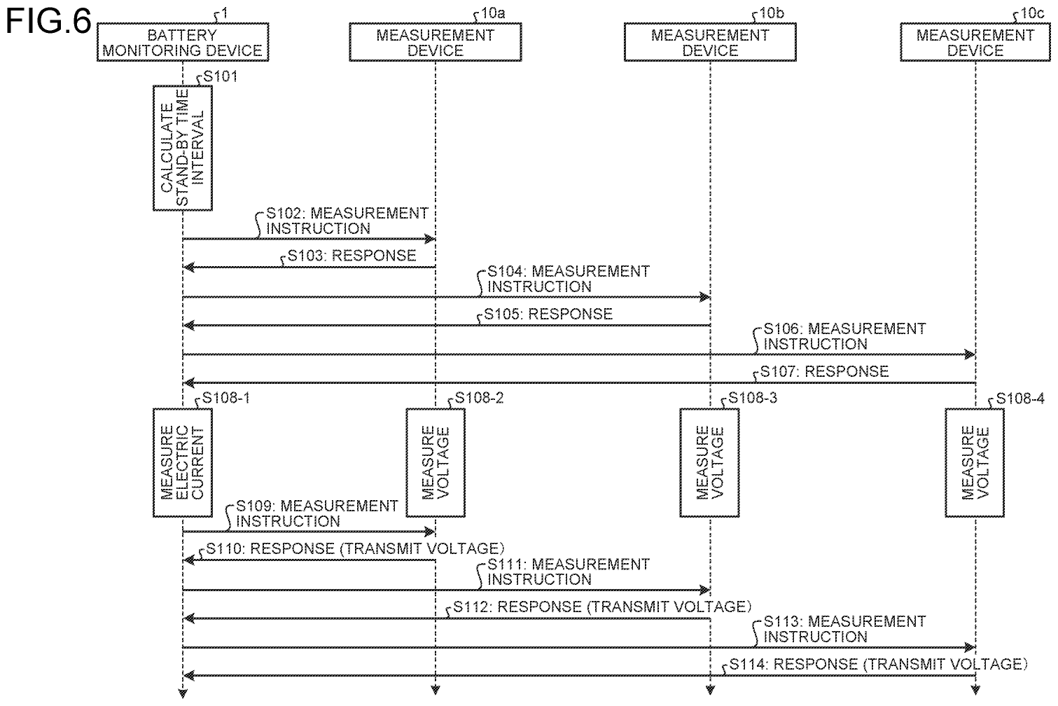

Next, with reference to FIG. 6, a processing procedure for processes that are executed in the battery monitoring system S according to the embodiment will be explained. FIG. 6 is a timing diagram illustrating a processing procedure of processes that are executed in the battery monitoring system S according to the embodiment.

As illustrated in FIG. 6, the battery monitoring device 1 calculates a stand-by time interval for each of the measurement devices 10 (Step S101). Specifically, the battery monitoring device 1 calculates a stand-by time interval obtained by totaling the individual time interval Di that is different for each of the measurement devices 10 and the common time interval Dc that is common to each of the measurement devices 10.

Next, the battery monitoring device 1 gives a measurement instruction for measuring a cell state to the measurement device 10a having a first communication sequence during a communication period (Step S102). Specifically, the battery monitoring device 1 transmits to the measurement device 10a, by a unicast method, a measurement instruction including a stand-by time interval corresponding to the measurement device 10a.

Next, in a case where receiving a measurement instruction, the measurement device 10a analyzes a stand-by time interval from the measurement instruction, and further transmits, to the battery monitoring device 1, a response that indicates completion (completion of analysis of stand-by time interval) of receiving a measurement instruction after completion of analysis (Step S103).

Next, the battery monitoring device 1 gives a measurement instruction of a cell state to the measurement device 10b having the next communication sequence during a communication period (Step S104). Specifically, the battery monitoring device 1 transmits, to the measurement device 10b, a measurement instruction including a stand-by time interval corresponding to the measurement device 10b by a unicast method.

Next, in a case where receiving a measurement instruction, the measurement device 10b analyzes a stand-by time interval from the measurement instruction, and further transmits, to the battery monitoring device 1, a response that indicates completion (completion of analysis of stand-by time interval) of receiving a measurement instruction after completion of analysis (Step S105).

Next, the battery monitoring device 1 gives a measurement instruction of a cell state to the measurement device 10c having the next communication sequence during a communication period (Step S106). Specifically, the battery monitoring device 1 transmits, to the measurement device 10c, a measurement instruction including a stand-by time interval corresponding to the measurement device 10c by a unicast method.

Next, in a case where receiving a measurement instruction, the measurement device 10c analyzes a stand-by time interval from the measurement instruction, and further transmits, to the battery monitoring device 1, a response that indicates completion (completion of analysis of stand-by time interval) of receiving the measurement instruction after completion of analysis (Step S107).

Next, the battery monitoring device 1 acquires a current value from the electric-current sensor 100 at a measurement timing of the measurement device 10 (Step S108-1), each of the measurement devices 10a to 10c measures a cell voltage at a measurement timing after a stand-by time interval elapsed (Step S108-2 to Step S108-4).

Next, the battery monitoring device 1 gives a measurement instruction of a cell state to the measurement device 10a having a first communication sequence during a next communication period after measurement (Step S109). Specifically, the battery monitoring device 1 transmits, to the measurement device 10a, a measurement instruction including a stand-by time interval corresponding to the measurement device 10a by a unicast method.

Next, in a case where receiving a measurement instruction, the measurement device 10a analyzes a stand-by time interval from the measurement instruction, and further transmits, to the battery monitoring device 1, a response that indicates completion (completion of analysis of stand-by time interval) of receiving the measurement instruction after completion of analysis (Step S110). Furthermore, the measurement device 10a transmits, to the battery monitoring device 1, a cell voltage measured in Step S108-2 in addition to transmission of the response.

Next, the battery monitoring device 1 gives a measurement instruction of a cell state to the measurement device 10b having the next communication sequence (Step S111). Specifically, the battery monitoring device 1 transmits, to the measurement device 10b, a measurement instruction including a stand-by time interval corresponding to the measurement device 10b by a unicast method.

Next, in a case where receiving a measurement instruction, the measurement device 10b analyzes a stand-by time interval from the measurement instruction, and further transmits, to the battery monitoring device 1, a response that indicates completion (completion of analysis of stand-by time interval) of receiving the measurement instruction after completion of analysis (Step S112). Furthermore, the measurement device 10b transmits, to the battery monitoring device 1, a cell voltage measured in Step S108-3 in addition to transmission of the response.

Next, the battery monitoring device 1 gives a measurement instruction of a cell state to the measurement device 10c having the next communication sequence (Step S113). Specifically, the battery monitoring device 1 transmits, to the measurement device 10c, a measurement instruction including a stand-by time interval corresponding to the measurement device 10c by a unicast method.

Next, in a case where receiving a measurement instruction, the measurement device 10c analyzes a stand-by time interval from the measurement instruction, and further transmits, to the battery monitoring device 1, a response that indicates completion (completion of analysis of stand-by time interval) of receiving the measurement instruction after completion of analysis (Step S114). Furthermore, the measurement device 10c transmits, to the battery monitoring device 1, a cell voltage measured in Step S108-4 in addition to transmission of the response.

As described above, the battery monitoring system S according to the embodiment includes a plurality of measurement devices and a battery monitoring device. Each of the plurality of measurement devices 10 measures a cell state of a corresponding one of the plurality of cells 51 constituting the battery 50. The battery monitoring device 1 sequentially communicates, by using wireless communication, with the plurality of measurement devices 10 during a communication period; and acquires state information indicating the cell state from each of the plurality of measurement devices 10. In a case where transmitting a corresponding measurement instruction of the cell state to each of the plurality of measurement devices 10, the battery monitoring device 1 transmits, to each of the plurality of measurement devices 10, a corresponding stand-by time interval such that measurement timings of the plurality of measurement devices 10 synchronize with each other, the stand-by time interval being a time interval from reception of the measurement instruction until the measurement timing. Each of the plurality of measurement devices 10 measures the corresponding cell state in a case where the stand-by time interval has elapsed since reception of the measurement instruction.

Thus, even with wireless communication using a unicast method, in a case where stand-by time intervals whose measurement timings of the plurality of measurement devices 10 synchronize with each other are calculated, it is possible to synchronize measurement timings of the plurality of measurement devices 10 with each other.

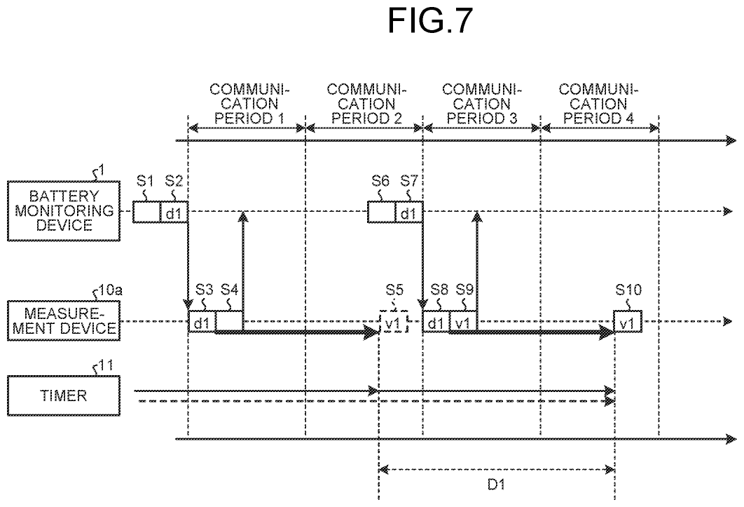

Next, with reference to FIG. 7, a process for detecting presence/absence of failure in a measuring process of the measurement device 10 will be explained. FIG. 7 is a diagram illustrating a process for detecting presence/absence of failure in a measuring process in the measurement device 10. Note that in FIG. 7, for convenience of explanation, the measurement devices 10b and 10c are omitted so as to indicate the measurement device 10a alone.

Steps S1 to S9 illustrated in FIG. 7 are processes (S9) from execution of a process for calculating (S1) a stand-by time interval by the battery monitoring device 1 to transmission of state information indicating a cell state, and thus are corresponding to Steps S1 to S21 illustrated in FIG. 1B. Step S10 illustrated in FIG. 7 is a process for measuring a cell state after the stand-by time interval d1 elapsed, which is received in Step S8.

As illustrated in FIG. 7, the measurement device 10a includes the timer 11 that measures a time interval. Note that each of the measurement devices 10b and 10c, whose illustration is omitted, also individually includes a corresponding timer. The measurement device 10a measures an elapsed time interval of a measuring process of a cell state by using the timer 11. In other words, the measurement device 10a measures time interval information that includes an elapsed time interval from the last measurement of a cell state until the present measurement. In the example illustrated in FIG. 7, the timer 11 is reset and restarts in Step S5 that is a measuring process, the timer 11 is reset and restarts again in Step S10 that is the next measuring process. Next, the measurement device 10a transmits, to the battery monitoring device 1, measured time interval information in association with state information.

In a case where a cell state is normally measured in each of Step S5 and Step S10, an elapsed time interval of the timer 11 in Step S10 is a time interval D1. On the other hand, in a case where the measurement device 10a fails in a measuring process in Step S5, and further succeeds in a measuring process in Step S10, an elapsed time interval of the timer 11 in Step S10 becomes an elapsed time interval from a measurement time point before Step S5, and thus is a time interval that is longer than the time interval D1. Note that in a case where a measuring process in Step S5 fails, a cell state that is transmitted in Step S9 is an old cell state that is measured before Step S5.

Thus, on the basis of time interval information associated with state information, the battery monitoring device 1 determines whether or not a measuring process in the last measurement fails for each of the measurement devices 10. Specifically, in a case where an elapsed time interval, which is time interval information, is longer than a predetermined threshold (time interval D1), the battery monitoring device 1 determines that a measuring process (Step S5) in the last measurement fails. In other words, the battery monitoring device 1 determines that state information transmitted in Step S9 is a cell state before Step S5.

In wireless communication, disadvantage is generally larger in terms of reliability in communication, a communication time interval, and the like as a transmission data amount is larger, so that it is desirable that a transmission data amount is small. However, as described above, in a case where state information is associated with time interval information, it is true that a transmission data amount may increase, but it is possible to precisely detect the fact that the measurement device 10 fails in a measuring process in the last measurement.

Next, with reference to FIG. 8, a process for detecting presence/absence of failure in reception of a measurement instruction in the measurement device 10. FIG. 8 is a diagram illustrating a process for detecting presence/absence of failure in reception of a measurement instruction in the measurement device 10.

Note that Steps S1 to S10 illustrated in FIG. 8 are the same processes as Steps S1 to S10 illustrated in FIG. 7, and thus explanation of processing details is omitted.

As illustrated in FIG. 8, the measurement device 10a measures, by using the timer 11, an elapsed time interval from reception of the last measurement instruction until reception of the present measurement instruction, and on the basis of the measure elapsed time interval, further determines whether or not reception of the present measurement instruction fails.

Specifically, the measurement device 10a resets and restarts the timer 11 in each of Step S3 and S8 that are reception timings of a measurement instruction. Herein, in a case where reception of a measurement instruction succeeds in both of Steps S3 and S8, in Step S9 for starting to count a stand-by time interval, an elapsed time interval of the timer 11 becomes a time interval until Step S8, namely, a time interval D2. On the other hand, in a case where reception of a measurement instruction in Step S3 succeeds and reception of a measurement instruction in Step S8 fails, an elapsed time interval of the timer 11 is not reset so as to be a time interval that is longer than the time interval D2.

In other words, in a case where an elapsed time interval from reception of the last measurement instruction is longer than a predetermined threshold (time interval D2), the measurement device 10a determines that reception of the present measurement instruction fails. As described above, in a case where measuring an elapsed time interval from reception of the last measurement instruction, it is possible to precisely determine whether or not reception of the present measurement instruction fails.

In a case where failing in reception of the present measurement instruction, the measurement device 10a cannot determine the present stand-by time interval d1, and thus measures a cell state at a measurement timing that is based on the last stand-by time interval. In other words, in a case where failing in reception of a measurement instruction in Step S8, the measurement device 10a starts to count a stand-by time interval from Step S9 by using a stand-by time interval in a measurement instruction received in Step S3. Note that a length of a communication period and a communication sequence are preliminarily fixed, a measurement timing does not deviate from those of the measurement devices 10b and 10c even when the last stand-by time interval is used. Thus, it is possible to execute synchronization with measurement timings of other devices of the measurement devices 10b and 10c by using the last stand-by time interval even in a case where reception of a stand-by time interval fails.

Note that in FIG. 8, a case is explained where a measurement instruction is not received in Step S8, for example, a case may also occur where a measurement instruction received in Step S8 is abnormal, in other words, a bug occurs in data of a measurement instruction and/or a stand-by time interval, for example. In this case, a stand-by time interval of the timer 11 is the time interval D2, thereby leading to determination that reception succeeds even in a case where a measurement instruction is abnormal.

In a case where the present measurement instruction whose reception succeeds is abnormal, the measurement device 10a measures a cell state at a measurement timing that is based on the last stand-by time interval. Specifically, in a case where executing an analysis process in Step S8 on the received measurement instruction so as to detect an abnormality that a stand-by time interval cannot be read (or, cannot be read as measurement instruction), the measurement device 10a starts to count a stand-by time interval from Step S9 by using a stand-by time interval in a measurement instruction that is received in Step S3. Thus, even in a case where a received measurement instruction abnormal, when the last stand-by time interval is used, it is possible to execute synchronization of measurement timings with other devices of the measurement devices 10b and 10c.

Note that in a case where measuring a cell state at a measurement timing that is based on the last stand-by time interval, the measurement device 10a may transmit, in transmitting state information, abnormality information indicating failure in reception of a measurement instruction or an abnormality in the received measurement instruction in association with the state information. Thus, the battery monitoring device 1 is capable of using state information associated with abnormality information not as a regular value, but as a reference value having possibility that a measurement timing of state information is not synchronized even just a little.

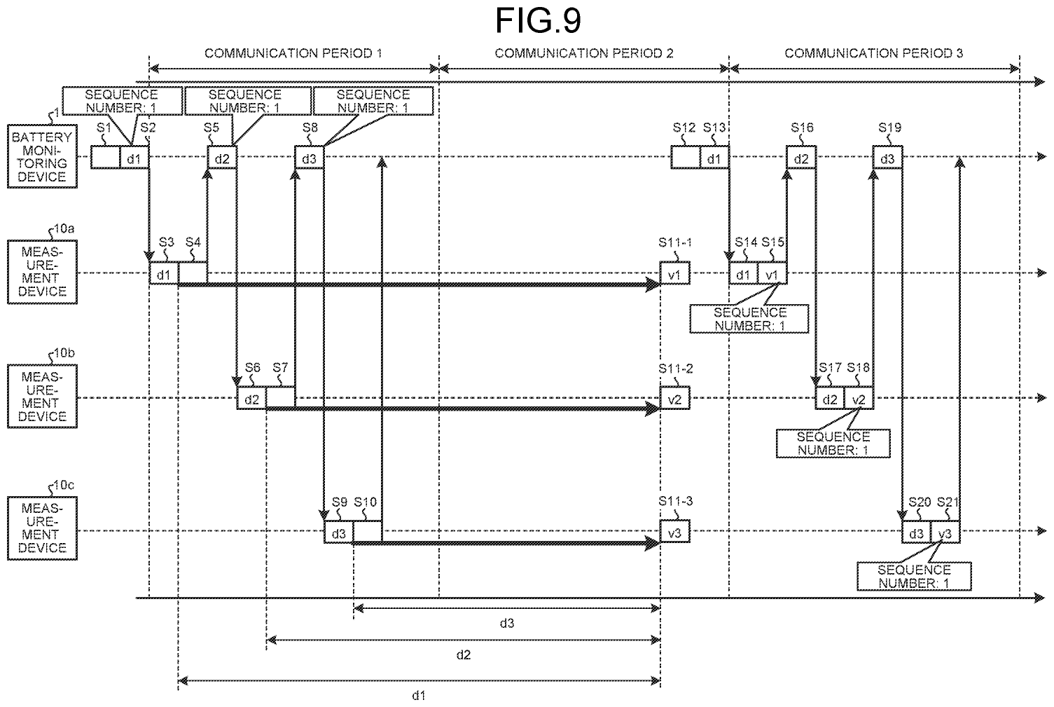

Next, with reference to FIG. 9, a process for detecting, by using a sequence number corresponding to a communication period, presence/absence of failure in a measuring process in the measurement device 10 will be explained. FIG. 9 is a diagram illustrating a process for detecting presence/absence of failure in a measuring process in the measurement device 10.

Note that basic processing details of Step S1 to Step S21 illustrated in FIG. 9 are similar to processing details of Step S1 to Step S21 illustrated in FIG. 1B so as to omit explanation thereof, and processing related to a sequence number will be mainly explained.

As illustrated in FIG. 9, the battery monitoring device 1 transmits, to each of the measurement devices 10, a corresponding sequence number that is associated with each communication period. In an example illustrated in FIG. 9, the battery monitoring device 1 transmits, to each of the measurement devices 10, a sequence number 1 corresponding to the communication period 1 along with a measurement instruction. Specifically, the battery monitoring device 1 transmits, in Steps S2, S5, and S8 during the communication period 1, a measurement instruction associated with the sequence number 1 along with a stand-by time interval.

In Steps S15, S18, and S21 during the communication period 3, each of the measurement devices 10 transmits a corresponding sequence number to the battery monitoring device 1 in association with state information. On the basis of collected sequence numbers associated with state information, the battery monitoring device 1 determines whether or not a measuring process of a cell state fails for each of the measurement devices 10.

Specifically, in a case where all of the sequence numbers associated with state information, which are received in the communication period 3, coincide with each other, the battery monitoring device 1 determines that all of the measurement devices 10 succeed in a measuring process. On the other hand, in a case where at least one of sequence numbers associated with state information is different from the others, the battery monitoring device 1 determines that the measurement device 10 that transmitted state information of the different sequence number fails in a measuring process.

In a case where there presents the measurement device 10 that fails in a measuring process, the battery monitoring device 1 employs state information that is received from the measurement device 10 that succeeds in the measuring process. The battery monitoring device 1 may ignore state information received from the measurement device 10 that fails in a measuring process, or may treat it not as a regular value but as a reference value including possibility that a measurement timing of state information is not synchronized even a little.

In this case where, the battery monitoring device 1 stores information on failure in a measuring process with respect to the measurement device 10 that fails in a measuring process, and in a case where detecting an abnormality, such as continuous failures, may execute an abnormality process such as resetting the measurement device 10 that fails in a measuring process.

As described above, the battery monitoring system S associates a sequence number corresponding to a communication period with state information, so that it is possible to determine whether or not each of the measurement devices 10 fails in a corresponding measuring process from a sequence number.

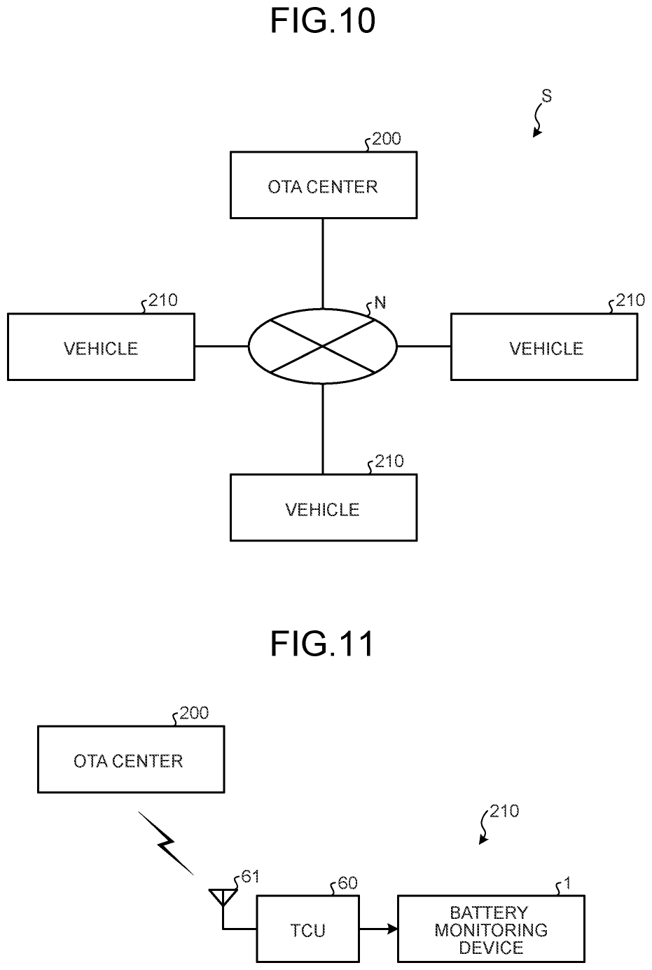

Note that the above-mentioned embodiment is merely one example, and for example, a program of the battery monitoring device 1 may be updated by using communication between an external server and a vehicle. This point will be explained with reference to FIG. 10 to FIG. 13.

FIG. 10 and FIG. 11 are diagrams each illustrating a configuration example of the battery monitoring system S according to a modification.

As illustrated in FIG. 10, in the battery monitoring system S according to the modification, an Over The Air (OTA) 200 and a vehicle 210 are connected via a communication network N. A wireless communication network, such as 5G, LTE, and Wi-Fi (Registered Trademark), is employed for the communication network N.

The battery monitoring system S according to the modification executes wireless communication between the OTA center 200 and the vehicle 210, and further acquires update data of the battery monitoring device 1 from the OTA center 200 so as to update a program and the like.

Furthermore, as illustrated in FIG. 11, in the battery monitoring system S, each of the vehicles 210 includes a Telematics Control Unit (TCU) 60 that receives update data from the OTA center 200.

The TCU 60 is an on-vehicle communication unit that includes an antenna 61 so as to communicate with the OTA center 200 via the communication network N, and further is connected to the communication network N so as to execute communication between the OTA center 200 and the vehicle 210.

Next, a flow of data update of the battery monitoring system S according to the modification will be explained.

In a case where there presents a program to be updated, the OTA center 200 transmits, via the communication network N, update data to the TCU 60 under a state where an ignition switch of the vehicle 210 is turned ON. Note that the ignition switch is an electric power source switch of a vehicle.

The TCU 60 transmits, via the antenna 61, update data received from the OTA center 200 to a communication unit 2 of the battery monitoring device 1. The TCU 60 inquires update of the OTA center 200 so as to recognize presence/absence of update.

The battery monitoring device 1 stores, in the storage 4, update data that is received from the TCU 60 via the communication unit 2. The storing of update data is executed under a state where an ignition switch is turned ON. It is sufficient that an ignition switch is turned ON for the storing of update data, and the storing of update data may be executed during running of a vehicle.

In a case where all downloads of update data via the TCU 60 has completed, the battery monitoring device 1 is turned into a state where update is possible. Herein, in a case where an ignition switch of the vehicle 210 is turned OFF, the controller 3 of the battery monitoring device 1 executes update on the basis of update data stored in the storage 4.

In the modification, an example is indicated in which the battery monitoring device 1 is updated in a case where an ignition switch is turned OFF. However, not limited there to. The fact that the battery monitoring device 1 is turned into a state where update is possible may be reported to an occupant such as a driver, and whether or not accepting the update may be received therefrom. The battery monitoring device 1 may be configured to be updated in a case where an ignition switch is turned OFF after an occupant such as a driver accepts the update.

A case will be explained where an example is applied to the present disclosure in which wireless communication is executed between the above-mentioned OTA center 200 and the vehicle 210, and update data of the battery monitoring device 1 is acquired so as to update a program and the like.

A basic embodiment according to the present disclosure will be explained regardless of update using update data.

As described above, the plurality of measurement devices 10 measures respective cell states of the plurality of cells 51 in accordance with measurement instructions of the battery monitoring device 1. The measurement device 10a measures a cell voltage of the cell 51a, the measurement device 10b measures a cell voltage of the cell 51b, and the measurement device 10c measures a cell voltage of the cell 51c.

For example, the battery monitoring device 1 is connected to the plurality of measurement devices 10 by time-divisional wireless communication to be able to communicate with each other, and further acquires state information indicating cell states from the plurality of measurement devices 10. Specifically, the battery monitoring device 1 sequentially communicates with the plurality of measurement devices 10 by using wireless communication during a communication period. In other words, the battery monitoring device 1 executes time division on a communication period, and further is communicably connected to the plurality of measurement devices 10 during a predetermined time interval by a unicast method that executes one-on-one sequential communication.

Next, update of the battery monitoring device 1 that is based on update data transmitted from the OTA center 200 will be explained. The update data corresponds to a battery monitoring program.

In the above-mentioned embodiment, in a case where transmitting a measurement instruction of a cell state to each of the plurality of measurement devices 10, the battery monitoring device 1 transmits, to the plurality of measurement devices 10, stand-by time intervals of the plurality of measurement devices 10 from reception of a measurement instruction until a measurement timing such that measurement timings of the plurality of measurement devices 10 synchronize with each other. Each of the plurality of measurement devices 10 receives, from the battery monitoring device 1, respective measurement instructions by a unicast method, and further measures cell states at measurement timings each of which is a timing at which a corresponding stand-by time interval has elapsed since reception of the measurement instruction. The above-mentioned embodiment is based on a hypothesis that a battery monitoring program that executes such operations is previously installed in the battery monitoring device 1. However, a battery monitoring program may be installed, after the fact, by update that is based on update data from the OTA center 200.

For example, the update data from the OTA center 200 may be a battery monitoring program that transmits, to the plurality of measurement devices 10, stand-by time intervals of the plurality of measurement devices 10 from reception of a measurement instruction until a measurement timing such that measurement timings of the plurality of measurement devices 10 synchronize with each other in a case where transmitting a measurement instruction of a cell state to each of the plurality of measurement devices 10. Each of the plurality of measurement devices 10 receives a measurement instruction by a unicast method from the updated battery monitoring device 1, and further measures a cell state at a measurement timing that is a timing at which a stand-by time interval has elapsed since reception of the measurement instruction.

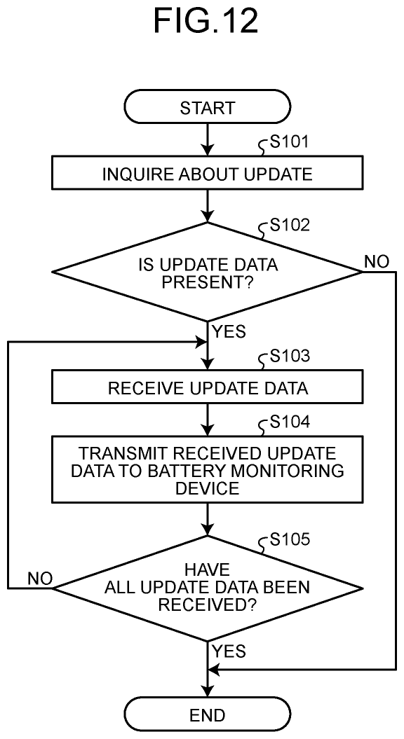

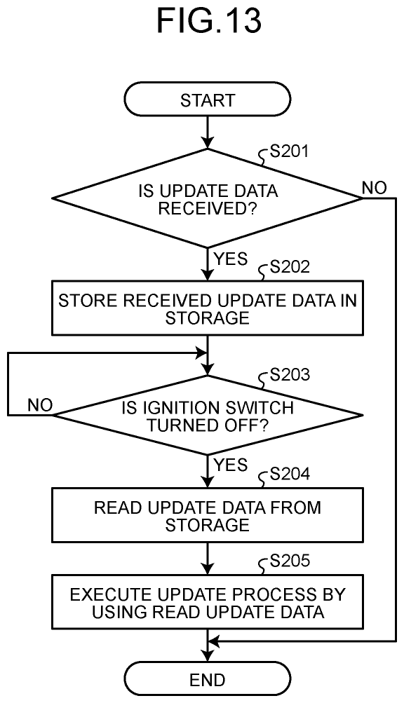

Next, with reference to FIG. 12 and FIG. 13, details of processing of the battery monitoring system S according to the modification will be explained. FIG. 12 is a flowchart illustrating a processing procedure of processes to be executed by the TCU 60 according to the modification.

As illustrated in FIG. 12, the TCU 60 inquires presence/absence of update data of the OTA sensor 200 (Step S101). Next, the TCU 60 determines whether or not a response transmitted from the OTA sensor 200 includes update data (Step S102).

In a case where update data is present (Step S102: Yes), the TCU 60 receives update data from the OTA sensor 200 (Step S103). In a case where update data is absent (Step S102: No), the TCU 60 ends the processing.

Next, the TCU 60 transmits the received update data to the battery monitoring device 1 (Step S104). Specifically, update data transmitted from the OTA sensor 200 is associated with identification information that indicates a target device, and in a case where the above-mentioned identification information indicates the battery monitoring device 1, the TCU 60 transmits update data to the battery monitoring device 1.

Next, the TCU 60 determines whether or not having received all update data from the OTA sensor 200 (Step S105), and in a case where all update data have been received (Step S105: Yes), ends the processing. Note that in a case where all update data have not been received (Step S105: No), in other words, in a case where there presents update data to be received in the OTA sensor 200, the TCU 60 returns the processing to Step S103 so as to receive update data again.

FIG. 13 is a flowchart illustrating a processing procedure of processes to be executed by the battery monitoring device 1 according to the modification. As illustrated in FIG. 13, the battery monitoring device 1 determines whether or not having received update data from the TCU 60 (Step S201).

In a case where receiving update data from the TCU 60 (Step S201: Yes), the battery monitoring device 1 stores the received update data in the storage 4 (Step S202). In a case where not having received update data (Step S201: No), the battery monitoring device 1 ends the processing.

Next, the battery monitoring device 1 determines whether or not an ignition switch of the vehicle 210 is turned OFF (Step S203). In a case where the ignition switch is turned OFF (Step S203: Yes), the battery monitoring device 1 reads update data from the storage 4 (Step S204). Note that the ignition switch is not turned OFF (Step S203: No), the battery monitoring device 1 repeatedly executes Step S203 until the ignition switch is turned OFF.

Next, the battery monitoring device 1 updates a battery monitoring program by using the read update data (Step S205), and further ends the processing. Note that in a case where the update data includes update data of the measurement device 10, the battery monitoring device 1 transmits update data to the measurement device 10. Thus, the measurement device 10 is capable of updating a battery monitoring program in accordance with update data.

The battery monitoring device 1, the measurement device 10, and the method thereof disclosed in the present disclosure may be realized by a processor that is programmed to execute one or more functions that are embodied by a battery monitoring program and a dedicated computer constituted of a memory. Or the battery monitoring device 1, the measurement device 10, and the method thereof disclosed in the present disclosure may be realized by a dedicated computer constituted of a processor that is constituted of one or more dedicated hardware logic circuits.

The battery monitoring device 1, the measurement device 10, and the method thereof disclosed in the present disclosure may be realized by one or more dedicated computers constituted of a combination of a processor and a memory programed to execute one or more functions, and a processor that is constituted of one or more dedicated hardware logic circuits. The program may be stored in a non-transitory computer readable medium as an instruction to be implemented by a computer.

The storage 4 of the battery monitoring device 1 may hold a program before update even after execution of update based on update data. Thus, in a case where update data is abnormal, it is possible to operate by using the program before update.

Moreover, the following configuration may be employed.

The TCU 60 transmits update data received from the OTA center 200 to the communication unit 20 of the measurement device 10 via the antenna 61. The measurement device 10 stores, in the storage 40, the update data received from the antenna 61 via the communication unit 20. In a case where all downloads of update data via the TCU 60 has completed, the measurement device 10 is turned into a state where update is possible. Herein, in a case where an ignition switch is turned OFF, the controller 30 of the measurement device 10 executes update on the basis of update data stored in the storage 40.

Update of the measurement device 10 is not limited to the above-mentioned example. The controller 3 of the battery monitoring device 1 may execute update on the basis of update data so as to update the measurement device 10.

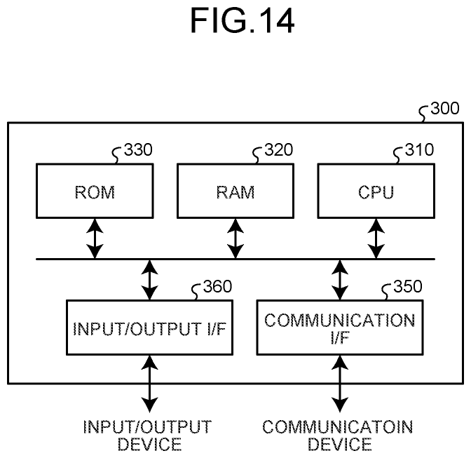

The above-mentioned battery monitoring device 1 according to the example implementation may be realized by using, for example, a computer 300 having a configuration illustrated in FIG. 14. Hereinafter, the battery monitoring device 1 is exemplified. FIG. 14 is a diagram illustrating a hardware configuration of one example of the computer 300 that realizes functions of the battery monitoring device 1. The computer 300 includes a CPU 310, a RAM 320, a ROM 330, a communication interface (I/F) 350, and an input/output interface (I/F) 360.

The CPU 310 operates on the basis of programs (e.g., non-transitory computer readable medium including stored instructions executed by a microprocessor) stored in the RAM 320 or the ROM 330, so as to control the various units. The ROM 330 stores therein a boot program that is to be executed by the CPU 310 at a start-up of the computer 300, programs that depend on hardware of the computer 300, etc.

The communication interface (I/F) 350 executes wired communication with other devices by Serial-Peripheral-Interface communication (SPI communication) and/or Controller-Area-Network communication (CAN communication). In a case where having a wireless communication function, the communication interface (I/F) 350 executes wireless communication with other devices by, for example, Wi-Fi (Registered Trademark), a Bluetooth-Low-Energy communication function (BLE communication), or the like. The communication interface (I/F) 350 receives data from another device in the battery monitoring device 1 and/or the measurement device 10, transmits the data to the CPU 310, and further transmits the data generated by the CPU 310 to the other device in the battery monitoring device 1 and/or the measurement device 10.

The CPU 310 controls, via the input/output interface 360, output of Pulse Width Modulation (PWM) and output via a port to another device, and Analog-to-Digital Converter (ADC) and input via a port from another device, and the like. The CPU 310 acquires, via the input/output interface 360, data from input devices. The CPU 310 outputs, via the input/output interface 360, generated data to output devices.

Note that in FIG. 2, a case is exemplified in which the battery monitoring device 1 includes the controller 3 having a single hardware configuration; however, the controller 3 may be realized by a multiple hardware configurations.

Note that in FIG. 2, a communication IC is exemplified as the communication unit 2; however, the communication unit 2 may be realized by a communication unit such as a micro-computer. Additionally, the communication unit 2 may be realized by a hardware configuration that is the same or similar to the hardware configuration illustrated in FIG. 14.

Note that the measurement device 10 may be realized by a hardware configuration that is the same or similar to the hardware configuration illustrated in FIG. 14. In FIG. 3, a case is exemplified in which the measurement device 10 includes the controller 30 having a single hardware configuration; however, the controller 30 may be realized by a multiple hardware configurations.

In FIG. 3, a communication IC is exemplified as the communication unit 20; however, the communication unit 20 may be realized by a communication unit such as a micro-computer. Additionally, the communication unit 20 may be realized by a hardware configuration that is the same or similar to the hardware configuration illustrated in FIG. 14.

In accordance with the present disclosure, it is possible to synchronize measurement timings.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A battery monitoring system comprising:
a plurality of measurement devices each of which measures a cell state of a corresponding one of a plurality of cells constituting a battery;
a battery monitoring device configured to:
by using wireless communication, sequentially communicate with the plurality of measurement devices during a communication period; and
acquire state information indicating the cell state from each of the plurality of measurement devices, wherein
in a case where transmitting a corresponding measurement instruction of the cell state to each of the plurality of measurement devices, the battery monitoring device transmits, to each of the plurality of measurement devices, a corresponding stand-by time interval such that measurement timings of the plurality of measurement devices synchronize with each other, the stand-by time interval being a time interval from reception of the measurement instruction until the measurement timing, and
each of the plurality of measurement devices measures the corresponding cell state in a case where the stand-by time interval has elapsed since reception of the measurement instruction.

2. The battery monitoring system according to claim 1, wherein
stand-by time intervals are different between the plurality of measurement devices.

3. The battery monitoring system according to claim 1, further comprising:
an electric-current sensor that measures a current value of the battery, wherein
the battery monitoring device determines the synchronized measurement timings as respective timings for acquiring the current value from the electric-current sensor.

4. The battery monitoring system according to claim 1, wherein
the plurality of measurement devices sequentially communicate with the battery monitoring device in a predetermined order, and
the battery monitoring device acquires, during a second communication period, pieces of the state information that is respectively measured by the plurality of measurement devices during a first communication period, the second communication period being a period of the first communication period or a period after the first communication period.

5. The battery monitoring system according to claim 4, wherein
the battery monitoring device decides, as the measurement timing, a timing going back to past by a time interval equal to or longer than a processing time interval needed for transmitting the state information elapsed from a communication timing with a first one of the measurement devices during second communication period.

6. The battery monitoring system according to claim 1, wherein
each of the plurality of measurement devices transmits, to battery monitoring device, time interval information in association with the state information, the time interval information being information on an elapsed time interval from a last measurement time point until a present measurement time point of the cell state.

7. The battery monitoring system according to claim 6, wherein
the battery monitoring device determines, for each of the measurement devices, whether or not a measuring process at a last measurement fails based on the time interval information.

8. The battery monitoring system according to claim 1, wherein
the battery monitoring device periodically transmits, to each of the plurality of measurement devices, the corresponding measurement instruction, and
each of the plurality of measurement devices determines whether or not reception of the present measurement instruction fails based on an elapsed time interval from reception of the last measurement instruction.

9. The battery monitoring system according to claim 8, wherein
in a case where failing in reception of the present measurement instruction, each of the plurality of measurement devices measures the cell state at the measurement timing based on the last stand-by time interval.

10. The battery monitoring system according to claim 8, wherein
in a case where the received present measurement instruction is abnormal, each of the plurality of measurement devices measures the cell state at the measurement timing based on the last stand-by time interval.

11. The battery monitoring system according to claim 1, wherein
each of the plurality of measurement devices transmits, to the battery monitoring device, a corresponding sequence number associated with a communication period in association with the corresponding state information, and
based on the sequence number, the battery monitoring device determines whether or not a measuring process of the cell state fails, for each of the measurement devices.

12. A battery monitoring device comprising:
a controller configure to:
by using wireless communication, sequentially communicate with a plurality of measurement devices during a communication period, each of the plurality of measurement devices measuring a cell state of a corresponding one of a plurality of cells constituting a battery; and
in a case where transmitting a corresponding measurement instruction of the cell state to each of the plurality of measurement devices; transmit, to each of the plurality of measurement devices, a corresponding stand-by time interval such that measurement timings of the plurality of measurement devices synchronize with each other, the stand-by time interval being a time interval from reception of the measurement instruction until the measurement timing.

13. A measurement device comprising:
a controller configured to:
measure a cell state of each of a plurality of cells constituting a battery; and
execute communication by using wireless communication during a communication period to transmit, to a battery monitoring device, state information indicating the cell state, and
the controller is further configured to:
from the battery monitoring device, receive a stand-by time interval from reception of a measurement instruction until the measurement timing, the stand-by time interval synchronizing the measurement timing of the measurement device and a measurement timing of another measurement device with each other; and
measure the cell state in a case where the stand-by time interval has elapsed since reception of the measurement instruction.

14. A battery monitoring method using:
a plurality of measurement devices each of which measures a cell state of a corresponding one of a plurality of cells constituting a battery;
a battery monitoring device configured to:
by using wireless communication, sequentially communicate with the plurality of measurement devices during a communication period; and
acquire state information indicating the cell state from each of the plurality of measurement devices, wherein
the battery monitoring method comprises:
in a case where the battery monitoring device transmits a corresponding measurement instruction of the cell state to each of the plurality of measurement devices, transmitting, to each of the plurality of measurement devices, a corresponding stand-by time interval such that measurement timings of the plurality of measurement devices synchronize with each other, the stand-by time interval being a time interval from reception of the measurement instruction until the measurement timing; and
measuring the corresponding cell state in a case where the stand-by time interval has elapsed since reception of the measurement instruction.

15. A non-transitory computer-readable recording medium having stored therein a battery monitoring program causing a battery monitoring system to execute a process, the battery monitoring system including: a plurality of measurement devices each of which measures a cell state of a corresponding one of a plurality of cells constituting a battery; and a battery monitoring device configured to: by using wireless communication, sequentially communicate with the plurality of measurement devices during a communication period; and acquire state information indicating the cell state from each of the plurality of measurement devices, and
the process comprising:
in a case where the battery monitoring device transmits a corresponding measurement instruction of the cell state to each of the plurality of measurement devices, transmitting, to each of the plurality of measurement devices, a corresponding stand-by time interval such that measurement timings of the plurality of measurement devices synchronize with each other, the stand-by time interval being a time interval from reception of the measurement instruction until the measurement timing; and
measuring the corresponding cell state in a case where the stand-by time interval has elapsed since reception of the measurement instruction.
